(19) United States
(12) Patent Application Publication
(10) Pub. No.: US 2026/0268965 A1
(43) Pub. Date: Sep. 10, 2026

(54) MEMORY, ACCESS METHOD THEREFOR AND ELECTRONIC DEVICE

(71) Applicant: BEIJING SUPERSTRING ACADEMY OF MEMORY TECHNOLOGY, Beijing (CN)

(72) Inventors: Jing Liang, Beijing (CN); Jin Dai, Beijing (CN); Yong Yu, Beijing (CN); Bokmoon Kang, Beijing (CN)

(73) Assignee: BEIJING SUPERSTRING ACADEMY OF MEMORY TECHNOLOGY, Beijing (CN)

(21) Appl. No.: 19/167,518

(22) PCT Filed: May 15, 2023
(86) PCT No.: PCT/CN2023/094290

§ 371 Date: Sep. 22, 2025

(30) Foreign Application Priority Data
Apr. 13, 2023 (CN) 202310395781.8

(51) Int. Cl. G11C 11/4096; G11C 5/06; G11C 11/4074; H10B 12/00

(52) U.S. Cl. CPC G11C 11/4096; G11C 5/063; G11C 11/4074; H10B 12/20

(57) ABSTRACT

The present disclosure provides a memory, an access method therefor and an electronic device. The memory comprises multiple memory cells, each memory cell comprising a first transistor and a second transistor; the first transistor is configured as a read transistor, and the second transistor is configured as a write transistor; the first transistor and the second transistor are sequentially distributed along a direction parallel to a substrate; the first transistor comprises a first gate electrode, a first semiconductor layer, a first electrode and a second electrode, and the second transistor comprises a second gate electrode, a second semiconductor layer, a third electrode and a fourth electrode; the first semiconductor layer is connected to the second semiconductor layer, and the second gate electrode multiplexes a back gate electrode of the first transistor, so that during a read operation, a second voltage is applied to the second gate electrode of the second transistor of a memory cell that does not need to be accessed, so as to adjust a threshold voltage of the first transistor, causing the first transistor of the memory cell that does not need to be accessed to be turned off. Using the present disclosure, data can be reliably read, and crosstalk can be avoided or effectively reduced.

### CROSS-REFERENCE TO RELATED APPLICATION

The present application is a U.S. National Phase Entry of International PCT Application No. PCT/CN 2023/094290 having an international filing date of May 15, 2023, which claims priority to Chinese Patent Application No. 202310395781.8 filed on Apr. 13, 2023. The above-identified applications are incorporated by reference herein in their entireties.

### TECHNICAL FIELD

The present disclosure relates to the field of memories, and in particular, the present disclosure relates to a memory, an access method therefor, and an electronic device.

### BACKGROUND

A conventional memory cell of a traditional Dynamic Random Access Memory (DRAM) includes a transistor and a capacitor. Due to cross-channel leakage, stored data needs to be refreshed frequently, which significantly increases power consumption. 2T0C has attracted much attention because it has no capacitor.

### SUMMARY

The present disclosure provides a memory and an access method therefor, and an electronic device.

In a first aspect, a memory is provided in an embodiment of the present disclosure, which includes a plurality of storage cells.

The storage cells include a first transistor and a second transistor, wherein the first transistor is configured as a read transistor and the second transistor is configured as a write transistor, and the first transistor and the second transistor are sequentially distributed in a direction parallel to a substrate.

The first transistor includes a first gate, a first semiconductor layer, a first electrode, a second electrode and a back gate, and the second transistor includes a second gate, a second semiconductor layer, a third electrode and a fourth electrode.

The first gate extends in the direction parallel to the substrate, the first semiconductor layer surrounds and is insulated from the first gate; the second gate extends in a direction perpendicular to the substrate, the second semiconductor layer surrounds and is insulated from the second gate.

The first gate is connected with the second semiconductor layer, and the first gate is connected with the third electrode, such that the first transistor is connected with the second transistor.

The first semiconductor layer is connected with the second semiconductor layer, and the second gate is reused as the back gate of the first transistor.

In a second aspect, an access method for a memory is provided in an embodiment of the present disclosure, wherein the memory further includes a read bit line, a read word line, a write bit line and a write word line; a plurality of storage cells are distributed in an array; a first electrode of the first transistor is connected with a read bit line, a second electrode of the first transistor is connected with a read word line, a first gate of the first transistor is connected with a third electrode of the second transistor, a fourth electrode of the second transistor is connected with a write bit line, and a second gate of the second transistor is connected with a write word line; the second gate is reused as a back gate of the first transistor;

The access method includes:
during a read operation phase, applying a first voltage to a write word line connected to one or more rows of storage cells to be accessed, such that the first voltage is applied to a back gate of a first transistor in the one row of storage cells, wherein the first voltage is used to adjust a threshold voltage of the first transistor to a first threshold voltage, and the first threshold voltage satisfies that the first transistor is in an off state when a storage signal is 0, and the first transistor is in an on state when the storage signal is 1;
and applying a second voltage to write word lines for storage cells in other rows that are not necessary to be accessed, such that the second voltage is applied to a back gate of a first transistor in the other rows of storage cells, wherein the second voltage is used to adjust the threshold voltage of the first transistor to a second threshold voltage, the second threshold voltage satisfies that the first transistor is in an off state in the read operation phase.

The second threshold voltage is greater than the first threshold voltage.

In a third aspect, a memory is provided in an embodiment of the present disclosure. The memory includes:
a read transistor and a write transistor.

The read transistor includes a first gate and a back gate, wherein the first gate extends along a first direction, the first gate includes a sidewall and two ends. At least one end and the sidewall are wrapped by one continuous first semiconductor layer and the first semiconductor layer is insulated from the first gate by a first gate dielectric layer.

The write transistor includes a second gate extending along a second direction, the second gate has a sidewall surrounded by a second semiconductor layer, a first semiconductor layer of a region corresponding to an end of the first gate wrapped by the first semiconductor layer is a part of the second semiconductor layer; the second gate is reused as the back gate.

In a fourth aspect, a semiconductor equipment is provided in an embodiment of the present disclosure. The semiconductor equipment includes:
a read transistor and a write transistor, wherein the read transistor includes a first gate and a back gate, the write transistor includes a second gate;
the back gate of the read transistor is connected with the second gate of the write transistor.

According to a fifth aspect, an electronic device is provided in an embodiment of the present disclosure. The electronic device includes any one of the memories or semiconductor equipment provided above.

The technical solutions provided in the embodiments of the present disclosure have at least the following beneficial effects.

According to the memory provided in the embodiments of the present disclosure, the gate of the write transistor is also used as the back gate of the read transistor, so that the read transistor is not necessarily to be a dual-gate structure, which can reduce the process difficulty and be widely used. In addition, by applying the second voltage to the gate of the write transistor of the unaccessed storage cell, i.e., applying the second voltage to the back gate of the read transistor, the threshold voltage of the read transistor is adjusted, the read transistor of the unaccessed storage cell is turned off, the data can be read reliably, and crosstalk can be avoided or effectively reduced.

Additional aspects and advantages of the present disclosure will be set forth in part in the following description, which will become apparent from the following description, or learned by the practice of the present disclosure.

### BRIEF DESCRIPTION OF DRAWINGS

The abovementioned and/or additional aspects and advantages of the present disclosure will become apparent and easy to understand from following description of embodiments in conjunction with accompanying drawings.

FIG. 1 is a schematic electrical diagram of a memory provided in an embodiment of the present disclosure.

FIG. 2 is a schematic electrical diagram of a storage cell in FIG. 1.

FIG. 3 illustrates schematically a perspective structure of the storage cell shown in FIG. 2.

FIG. 4 is a schematic cross-sectional view of the storage cell shown in FIG. 3 along an A-A line.

FIG. 5 illustrates schematically an Id-Vg graph of a transistor in a case where different voltages are applied to a back gate of the transistor according to an embodiment of the present disclosure.

### DETAILED DESCRIPTION

The present disclosure will be described below in detail. Examples of the embodiments of the present disclosure are illustrated in the accompanying drawings throughout which same or similar reference signs represent the same or similar components or components with the same or similar functions. In addition, detailed descriptions about a known technology are omitted if unnecessary to the illustrated features of the present disclosure. The embodiments described below with reference to the accompanying drawings are illustrative, and are merely intended to explain the present disclosure, which cannot be interpreted as a limitation on the present disclosure.

It can be understood by those skilled in the art that unless otherwise defined, all terms (including technical terms and scientific terms) used herein have the same meanings as commonly understood by those of ordinary skills in the art that to which the present disclosure pertains. It should also be understood that terms defined in, for example, a general dictionary, should be understood as having the same meanings as those in the context of the prior art, and may not be explained as idealized or too formal meanings, unless specifically defined as herein. It can be understood by those skilled in the art that unless otherwise specified, the singular forms “one”, “a/an”, “said”, and “the” used herein may also include plural forms. It should be further understood that wording “include” used in the specification of the present disclosure refers to existence of feature, integer, act, operation, element, and/or component, but does not exclude existence or addition of one or more other features, integers, acts, operations, elements, components, and/or combinations thereof. It should be understood that when we stating that an element is “connected” or “coupled” to another element, such element may be directly connected or coupled to other elements, or there may be intermediate elements. In addition, “connected” or “coupled” used herein may include wireless connection or wireless coupling. Wording “and/or” used herein includes all or any one and all combinations of one or more listed items that are associated.

Capacitance of an existing 1T1C DRAM storage cell structure is limited by a read operation, and cannot be significantly reduced. Therefore, there is still a challenge to a manufacturing process of large capacitors, which is one of main obstacles of DRAM 1T1C technologies.

A 2T0C DRAM storage cell structure has attracted much attention because of its lack of capacitors. In this scheme, data writing and data reading are separated and implemented by two transistors, Tr_w (write transistor) and Tr_r (read transistor), respectively, without capacitors. Therefore, 4 signals are required for read and write operations (Write WL and Write BL for write operations, Read WL and Read BL for read operations).

Compared to traditional 1T1C DRAM storage cell structures, this scheme does not require much capacitance at a storage node SN although due to non-destructive read characteristics. However, performing read operations is challenging due to crosstalk or current sharing issues between RWLs and RBLs in this 2T0C storage array.

In the present disclosure, a memory, an access method thereof, and an electronic device are provided, which can reliably read data and avoid or effectively reduce crosstalk.

Hereinafter, the technical solution of the present disclosure and how the technical solution of the present disclosure solves the abovementioned technical problems will be described in detail with reference to specific embodiments. The following specific embodiments may be combined with each other, and the same or similar concepts or processes may not be described in detail in some embodiments. Hereinafter, embodiments of the present disclosure will be described with reference to the accompanying drawings.

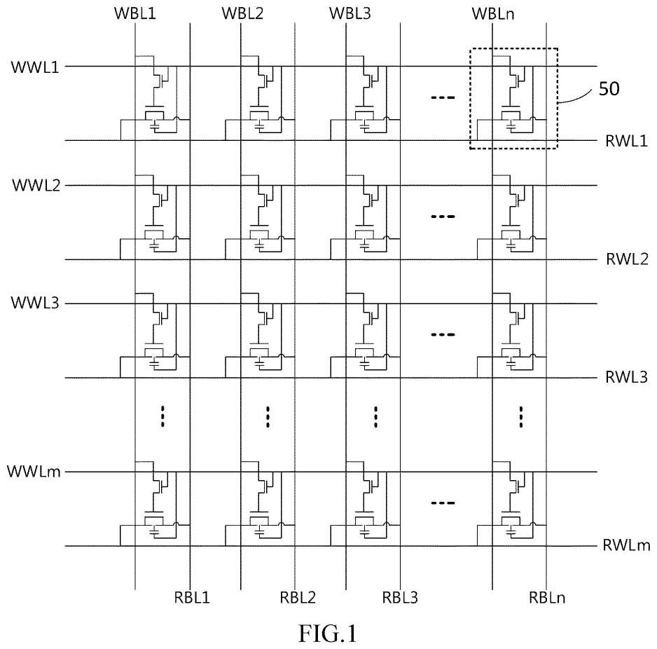

A memory is provided in an embodiment of the present disclosure. As shown in FIG. 1, the memory includes a plurality of storage cells 50 arranged in an array, a plurality of read bit lines (RBL1, RBL2, RBL3 . . . RBLn), a plurality of read word lines (RWL1, RWL2, RWL3 . . . RWLm), a plurality of write bit lines (WBL1, WBL2, WBL3 . . . WBLn), and a plurality of write word lines (WWL1, WWL2, WWL3 . . . WWLm).

A plurality of storage cells distributed in columns and rows constitute a storage cell array. All write transistors of storage cells in a row are connected to a same write word line WWL, and all read transistors of storage cells in a row are connected to a same read word line RWL. All write transistors of storage cells in a column are connected to a same write bit line WBL, and all read transistors of storage cells in a column are connected to a same read bit line RBL. Storage cells in different columns correspond to different write bit lines WBL and different read bit lines RBL. Storage cells in different rows correspond to different write word lines WWL and different read word lines RWL.

As in FIG. 1, a back gate of a read transistor in each storage cell is connected to a write word line WWL in that storage cell.

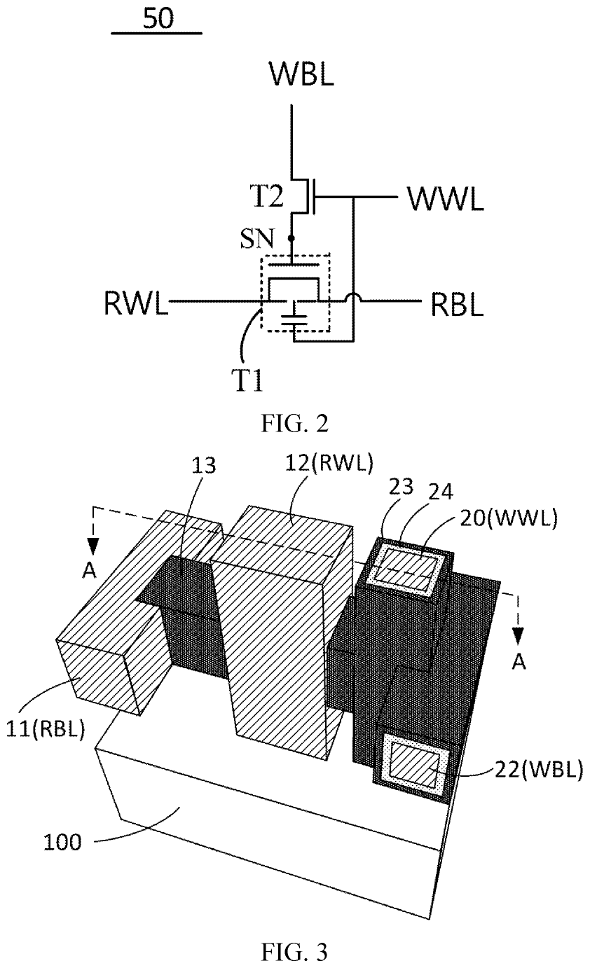

As shown in FIGS. 2, 3, and 4, a storage cell 50 includes a first transistor T1 and a second transistor T2, wherein the first transistor T1 is configured as a read transistor and the second transistor T2 is configured as a write transistor; the first transistor T1 and the second transistor T2 are sequentially distributed along a direction parallel to a substrate.

The first transistor T1 includes a first gate 10, a first semiconductor layer 13, a first electrode 11, a second electrode 12 and a back gate, and the second transistor T2 includes a second gate 20, a second semiconductor layer 23, a third electrode 21 and a fourth electrode 22.

The first gate 10 extends along a direction parallel to the substrate 100, and the first semiconductor layer 13 surrounds and is insulated from the first gate 10. The second gate 20 extends along a direction perpendicular to the substrate 100, and the second semiconductor layer 23 surrounds and is insulated from the second gate 20.

In one example, sidewalls of the first semiconductor layer 13 extend along a direction parallel to the substrate 100, and sidewalls of the second semiconductor layer 23 extend along a direction perpendicular to the substrate 100.

The first semiconductor layer 13 surrounds the first gate, which may be surrounded on a single side, on two sides, on three sides, or channel-all-around, and a cross section in a shape is of a single line or two lines, or a U-shape.

In some embodiments, the second semiconductor layer 23 may be of a channel-all-around type, and the second semiconductor layer 23 surrounds sidewalls of the second gate 20. For example, the second semiconductor layer 23 is annular, and a cross section of the second semiconductor layer 23 at each position of the second gate 20 fits to the second gate 20 in size.

In a specific embodiment, the first electrode 11 may be used as a part of the read bit line RBL, the second electrode 12 may be used as a part of the read word line RWL, the second gate 20 may be used as a part of the write word line WWL, and the fourth electrode 22 may be used as a part of the write bit line WBL, so that a 2T0C memory structure is simple and space-saving, which is beneficial to improving integration.

In an exemplary embodiment, the first gate 10 extends along a direction parallel to the substrate 100 and has sidewalls and two ends. The first semiconductor layer 13 surrounds only the sidewalls of the first gate 10, and the read bit line RBL and the read word line RWL are spaced apart along the sidewalls of the first gate 10 (not shown).

In another exemplary embodiment, the first gate 10 extends along a direction parallel to the substrate 100 and has sidewalls and two ends. The first semiconductor layer 13 surrounds the sidewalls and one end of the first gate 10, wherein the first semiconductor layer 13 provided at one end is reused as the second semiconductor layer 23. That is, the first semiconductor layer 13 surrounding one of the ends is a semiconductor layer shared by two transistors (not shown).

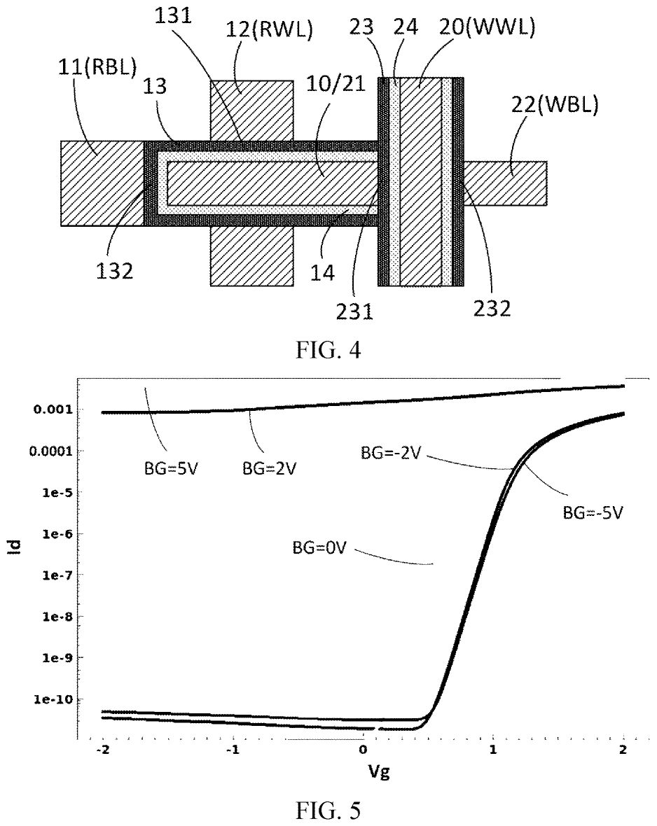

In yet another exemplary embodiment, the first gate 10 extends along a direction parallel to the substrate 100 and has sidewalls and two ends, the first semiconductor layer 13 surrounds the sidewalls and the two ends of the first gate 10, the read bit line RBL is connected with the first semiconductor layer 13 disposed at one end of the first gate 10, and the read word line RWL is located at a corresponding position on a sidewall of the first gate 10 and connected with the first semiconductor layer 13 surrounding the sidewalls of the first gate 10 (as shown in FIGS. 3 and 4).

The first gate 10 is connected with the second semiconductor layer 23, and the first gate 10 is reused as the third electrode 21 of the second transistor T2, so that the first transistor T1 and the second transistor T2 are connected. That is, the first gate 10 may be used as the third electrode 21 of the second transistor T2, in addition to as a gate of the first transistor T1.

The first semiconductor layer 13 is connected with the second semiconductor layer 23, and the second gate 20 is reused as a back gate of the first transistor T1. In a specific example, an end of the first semiconductor layer 13 is connected with a sidewall of the second semiconductor layer 23. Since the first semiconductor layer 13 is connected with the second semiconductor layer 23, both the first semiconductor layer 13 and the second semiconductor layer 23 can be used as a semiconductor layer of the read transistor (the first transistor T1), and the second gate 20 can control the first electrode 11 and the second electrode 12 connected with the first semiconductor layer 13, through the second semiconductor layer 23 and the first semiconductor layer 13. That is, the second gate 20 can be reused as a back gate of the first transistor T1 (read transistor).

That is, the second gate 20 may be used as the back gate of the first transistor T1 in addition to as a gate of the second transistor T2. In this way, during a read operation, a first voltage is applied to a second gate 20 of a second transistor T2 of a storage cell to be accessed. The first voltage can adjust a threshold voltage of the first transistor T1 because the second gate 20 is reused as the back gate of the first transistor T1, enabling the first transistor T1 of the storage cell to be accessed to be turned on when “1” is stored, and turned off when “0” is stored. A second voltage is applied to a second gate 20 of a second transistor T2 of an unaccessed storage cell, i.e., the second voltage is applied to the back gate of the first transistor T1, the threshold voltage of the first transistor T1 can be adjusted such that the first transistor T1 of the unaccessed storage cell is turned off (the first transistor is turned off regardless of that “0” or “1” is stored).

In some embodiments, both the first transistor T1 and the second transistor T2 are N-type transistors, for example, the semiconductor materials of the transistors are IGZO or similar materials for implementing N-type transistors.

Of course, the types of transistors in the embodiments of the present application are not limited, and all of them may be N-type or P-type, or one of them may be N-type and the other may be P-type. When the type of the transistor is changed, compared with the abovementioned example where both transistors are N-type transistors, there is a change in positive and negative voltages applied, but a logical relationship for switching on or switching off the transistor remains unchanged.

A technical solution, which is similar to the inventive concept of the present application and is achieved by changing the transistor into the N-type or the P-type, falls within the protection scope of the present application.

When a voltage of the back gate BG of the N-type transistor is positive, the threshold voltage of the N-type transistor is negatively shifted as the positive voltage of the back gate BG is greater. When a voltage of the back gate BG of the N-type transistor is negative, the threshold voltage of the N-type transistor is positively shifted as the negative voltage of the back gate BG is greater. FIG. 5 illustrates an Id-Vg graph of the N-type transistor when different voltages are applied to the back gate of the N-type transistor. As can be seen from FIG. 5, the more positive (higher) the voltage of the back gate BG is, the more negative the threshold voltage of the transistor is, and the easier the transistor is to turn on. Therefore, the threshold voltage of the first transistor T1 can be adjusted higher by applying a negative voltage to the second gate 20 of the second transistor T2 of the unaccessed storage cell, i.e., to the back gate of the first transistor T1, so that the first transistor T1 of the unaccessed storage cell is turned off. For example, a storage node SN of the storage cell stores data “1” (for example, the voltage is 1 V), the threshold voltage of the first transistor T1 is increased (for example, 2 V) by applying a negative voltage to the back gate of the first transistor T1, so that even if the storage node SN stores data “1”, the first transistor T1 cannot be turned on.

According to the memory provided in the embodiments of the present disclosure, the gate of the write transistor (i.e., the second transistor T2) is also used as the back gate of the read transistor (i.e., the first transistor T1), so that the back gate of the read transistor is not necessarily to be independent from the write transistor, which can reduce the process difficulty and be widely used. In addition, by applying the second voltage to the gate of the write transistor of the unaccessed storage cell, i.e., applying the second voltage to the back gate of the read transistor, the threshold voltage of the read transistor is adjusted, the read transistor of the unaccessed storage cell is turned off, the data can be read reliably, and crosstalk can be avoided or effectively reduced.

In some embodiments, as shown in FIGS. 2, 3, and 4, the first transistor T1 further includes a first gate dielectric layer 14, and the second transistor T2 further includes a second gate dielectric layer 24.

The first gate dielectric layer 14 is disposed between the first gate 10 and the first semiconductor layer 13, and surrounds the first gate 10. The first gate dielectric layer 14 is connected with the second semiconductor layer 23. The second gate dielectric layer 24 is disposed between the second gate 20 and the second semiconductor layer 23, and surrounds the second gate 20.

In some embodiments, a dielectric constant K value of the first gate dielectric layer 14 is less a the dielectric constant K value of the second gate dielectric layer 24. The dielectric constant K value is a constant relative to vacuum. That is, the K value is a relative dielectric constant. In some embodiments, the dielectric constant K value of the first gate dielectric layer 14 is less than 7, and the dielectric constant K value of the second gate dielectric layer 24 is greater than 7. The greater the value of the dielectric constant K is, a stronger control force the transistor has. Since the second gate 20 of the write transistor is used as the back gate of the read transistor, the threshold voltage of the read transistor (left transistor) can be controlled by controlling the second gate 20 of the write transistor. In the present disclosure, by setting the dielectric constant K value of the second gate dielectric layer 24 of the write transistor to be greater than 7, the control force is stronger, and the threshold voltage of the read transistor can be controlled better.

In some embodiments, as shown in FIGS. 2, 3, and 4, there are regions in which an orthographic projection of the first gate 10 and an orthographic projection of the second gate 20 are overlapped (incompletely overlapped), on a plane perpendicular to the substrate 100. The overlapping region is a region has an orthographic projection of the end of the first gate 10 on the plane. A non-overlapping region is a region other than the region where the end of the first gate 10 is orthographically projected on the plane. In other words, on a plane perpendicular to the substrate 100, the orthographic projection of the first gate 10 is located within the orthographic projection of the second gate 20, and the orthographic projection of the first gate 10 is not overlapped with the orthographic projection of the second gate 20.

In some embodiments, as shown in FIGS. 2, 3, and 4, both the first electrode 11 and the second electrode 12 are connected with the first semiconductor layer 13. The fourth electrode 22 is connected with the second semiconductor layer 23. In a cross section perpendicular to the substrate 100, all of the first electrode 11, the second electrode 12 and the first gate 10 are located on a first side of the second gate 20, and the fourth electrode 22 is located on a second side of the second gate 20, wherein the first side and the second side are opposite to each other.

The memory provided in the embodiments of the present disclosure is a 3D memory including a plurality of layers of storage cells 50 stacked along a direction perpendicular to the substrate 100. According to the 2T0C structure scheme provided in the embodiments of the present disclosure, the gate of the second transistor is a vertical structure and the channel is a horizontal channel and the second transistor is not stacked with the first transistor, so that the size of the storage cell in a direction perpendicular to the substrate can be reduced, and the 3D stack of the 2T0C storage cell with a compact structure can be conveniently manufactured, thus simplifying the process and reducing the cost.

In some embodiments, the channel of the first semiconductor layer 13 of the first transistor T1 is a horizontal channel with respect to a support surface of the support structure when the two transistors are placed on a support structure at intervals. In some embodiments, the channel of the second semiconductor layer 23 of the second transistor T2 is a horizontal channel.

Compared with the abovementioned scheme in which the two transistors are placed on the support structure at intervals, when the relative positions of the two transistors remain unchanged but are rotated by 90 degrees on the support structure, the channels of the two transistors are vertical channels with respect to the support surface of the support structure.

The relative positions of the two transistors in the present application are not changed, but whether they are arranged on one support surface at intervals or they are stacked and only one of the two transistors is arranged on the support structure belongs to the protection scope of the present application.

The horizontal channel described in an embodiment of the present disclosure can be understood as a non-perpendicular channel, and the horizontal channel can be an embodiment in which a length direction of the channel or a transport direction of carriers is in a plane parallel to the substrate.

In some embodiments, the horizontal channel may be a planar channel or an annular channel.

In the second transistor of the present disclosure, the gate extends along a second direction and the channel is a horizontal channel, which can facilitate manufacturing a stacked 3D structure in the second direction. Meanwhile, the first transistor has the first gate along the first direction and the channel along the first direction, thereby achieving a first transistor and a second transistor having a compact structure.

A parallel direction of the channel to the substrate may be approximately parallel, and the error may be within 10 degrees, depending on relative positions between the effective source and drain electrodes in practical applications. For example, outer contours of upper and/or lower surfaces of source and drain electrodes in a longitudinal cross section are on a plane that is approximately parallel to a major surface of the substrate.

In an exemplary embodiment, on a plane perpendicular to the substrate 100, an orthographic projection of the first electrode 11 may be overlapped with an orthographic projection of the first gate 10.

In an exemplary embodiment, the first electrode 11 may be disposed on a side of the second electrode 12 away from the second gate 20, and may be disposed on a side of the first gate 10 away from the second gate 20.

In an exemplary embodiment, the first semiconductor layer 13 may include a sidewall and two ends, the first semiconductor layer 13 includes a first source contact region 131 and a first drain contact region 132, wherein the first source contact region 131 is located at the sidewall of the first semiconductor layer 13, and the first drain contact region 132 is located at the sidewall of the first semiconductor layer 13 or at one of the two ends away from the second gate 20.

In an exemplary embodiment, on a plane parallel to the substrate 100, an orthographic projection of the first electrode 11 and an orthographic projection of the second electrode 12 may be not overlapped, and an orthographic projection of the third electrode 21 and an orthographic projection of the fourth electrode 22 may be not overlapped.

In an exemplary embodiment, on a plane parallel to the substrate 100, an orthographic projection of the second gate 20 may be located outside an orthographic projection of the third electrode 21, and an orthographic projection of the second gate 20 may be located outside an orthographic projection of the fourth electrode 22.

In an exemplary embodiment, the third electrode 21 and the fourth electrode 22 may be simultaneously formed by one manufacturing process, which is not limited thereto in the embodiments of the present disclosure, and they may be separately manufactured in different processes.

In an exemplary embodiment, the second gate 20 extends along a direction perpendicular to the substrate and has a sidewall, the second semiconductor layer 23 surrounds the sidewall of the second gate 20, and the second semiconductor layer 23 includes a second source contact region 231. The first gate 10 extends along a direction parallel to the substrate 100 and has a sidewall and two ends, the first semiconductor layer 13 at least surrounds the sidewall of the first gate 10, one of the two ends extends to the second source contact region 231 of the second semiconductor layer 23, so as to be connected with the second semiconductor layer 23.

In an exemplary embodiment, the sidewall of the second semiconductor layer 23 further includes a second drain contact region 232. The second source contact region 231 and the second drain contact region 232 are located in different regions of the sidewall of the second semiconductor layer 23, and orthographic projections of the second source contact region 231 and the second drain contact region 232 in a plane perpendicular to the substrate 100 have an overlap region such that a channel between the second source contact region 231 and the second drain contact region 232 is parallel to the substrate 100.

The sidewall of the first semiconductor layer 13 has a first source contact region 131 and a first drain contact region 132, and a channel between the first source contact region 131 and the first drain contact region 132 is parallel to the substrate 100.

In some embodiments, when both the transistors are N-type transistors, materials of the first semiconductor layer 13 and the second semiconductor layer 23 include a metal oxide semiconductor material. The material of the metal oxide may be Indium Gallium Zinc Oxide (IGZO). When the metal oxide material is IGZO, a leakage current of the transistor 11 is small (the leakage current is less than or equal to 10-15 A), thereby ensuring a low refresh rate of the dynamic memory. It should be noted that the material of the metal oxide may be ITO, IWO, ZnOx, InOx, In2O3, InWO, SnO2, TiOx, InSnOx, ZnxOyNz, MgxZnyOz, InxZnyOz, InxGayZnzOa, ZrxInyZnzOa, HfxInyZnzOa, SnxInyZnzOa, AlxSnyInzZnaOd, SixInyZnzOa, ZnxSnyOz, AlxZnySnzOa, GaxZnySnzOa, ZrxZnySnzOa, InGaSiO and other materials, as long as the leakage current of the transistor can meet the requirements, adjustments can be made specifically according to the actual situation.

In some embodiments, the metal in the metal oxide semiconductor material includes at least one of indium, tin, zinc, aluminum, gallium.

In the present disclosure, an electrode may be a source or a drain, and one of the two electrodes of the same transistor is a source and the other is a drain.

In the present disclosure, “parallel” refers to approximately parallel or almost parallel, for example, a state in which the angle formed by two straight lines is −10° or more and 10° or less, and therefore further includes a state in which the angle is −5° or more and 5° or less. In addition, “perpendicular” refers to “approximately perpendicular”, for example, a state in which the angle formed by two straight lines is 80 degrees or more and 100 degrees or less, and therefore further includes a state in which the angle is 85 degrees or more and 95 degrees or less.

Based on the same inventive concept, a memory is provided in an embodiment of the present disclosure. The memory includes a read transistor and a write transistor.

The read transistor includes a first gate and a back gate, wherein the first gate extends along a first direction, the first gate includes a sidewall and two ends. At least one end and the sidewall are wrapped by one continuous first semiconductor layer and the first semiconductor layer is insulated from the first gate by a first gate dielectric layer.

The write transistor includes a second gate, and the second gate extends along a second direction, wherein the second gate has a sidewall surrounded by a second semiconductor layer, and a first semiconductor layer of a region corresponding to an end of the first gate wrapped by the first semiconductor layer is a part of the second semiconductor layer. The second gate is reused as a back gate. That is, the second gate is used as the back gate of the read transistor at the same time, and the first transistor and the second transistor share the second gate.

The read transistor and the write transistor are disposed on a support surface, the first direction and the second direction are perpendicular to each other, one of the first direction and the second direction is parallel to the support surface and the other is perpendicular to the support surface. The drawings illustrate that the first direction is parallel to the support surface, but a first direction perpendicular to the support surface is also within the protection scope of the present application. As shown in FIG. 4, in the present application, the positional relationship between the transistor and the support surface is not defined, which can be implemented in the above two embodiments.

In the following embodiments, extension directions of the first gate and the second gate are approximately perpendicular to each other, and the positional relationship between the transistor and the support surface is not defined.

Based on the same inventive concept, a semiconductor equipment is provided in an embodiment of the present disclosure. The semiconductor equipment includes a read transistor including a first gate and a back gate, and a write transistor including a second gate. The back gate of the read transistor is connected with the second gate of the write transistor.

Extension directions of the first gate and the second gate are approximately perpendicular to each other.

An outer sidewall of the first gate is surrounded by a first semiconductor layer, and an outer sidewall of the second gate is surrounded by a second semiconductor layer. The first semiconductor layer is connected with the second semiconductor layer.

The first gate is connected with the second semiconductor layer.

The second gate is reused as a back gate.

In some embodiments, the first semiconductor layer and the second semiconductor layer are made of a same material, and the first semiconductor layer and the second semiconductor layer are of an integral structure.

In other embodiments, the first semiconductor layer and the second semiconductor layer may also be made of different materials, and the first semiconductor layer is coupled to the second semiconductor layer.

That is, the first semiconductor layer and the second semiconductor layer are connected, and may be of an integral structure. For example, during fabrication, a one-step deposition process forms the semiconductor layer located between the two transistor regions, and a continuous film layer is formed between the semiconductor layers. Alternatively, it is not limited to an integral type. Semiconductor layers of different materials may be coupled to each other, and contact between the semiconductor layers may be increased according to needs, so as to reduce or eliminate contact barriers.

Based on the same inventive concept, a storage cell circuit is provided in an embodiment of the present disclosure. As shown in FIG. 2, the storage cell circuit includes a read transistor T1 including a first gate and a back gate, and a write transistor T2 including a second gate.

In some embodiments, the back gate of the read transistor is connected with the second gate of the write transistor. The semiconductor layer of the read transistor is connected with a semiconductor layer of the write transistor.

The storage cell circuit refers to a logic circuit of one storage cell. The logic circuit described in the embodiment of the present disclosure has a 2T0C structure, whose circuit connection relationship is different from a circuit connection relationship of an existing 2T0C structure. In addition, the logic circuit corresponds to a new structure design.

Based on the same inventive concept, an electronic device is provided in an embodiment of the present disclosure. The electronic device includes a memory or a storage cell circuit as provided in any of the above embodiments.

The electronic device provided in the embodiment of the present disclosure has the same inventive concept and the same beneficial effects as those in the previous embodiments, and the contents related to the electronic device not shown in detail can be referred to the previous embodiments, which will not be repeatedly described here.

Based on the same inventive concept, a method for accessing a memory as provided in any of the above embodiments is provided in an embodiment of the present disclosure. As shown in FIGS. 1 and 2, the memory further includes a plurality of read bit lines (RBL1, RBL2, RBL3 . . . RBLn), a plurality of read word lines (RWL1, RWL2, RWL3 . . . RWLm), a plurality of write bit lines (WBL1, WBL2, WBL3 . . . WBLn) and a plurality of write word lines (WWL1, WWL2, WWL3 . . . WWLm).

A plurality of storage cells constitute a plurality of storage cell rows and a plurality of storage cell columns. Each of storage cells in a row is connected with a write word line WWL and a read word line RWL. Each of storage cells in a column is connected with a write bit line WBL and a read bit line RBL. Storage cells in different columns correspond to different write bit lines WBL and different read bit lines RBL. Storage cells in different rows correspond to different write word lines WWL and different read word lines RWL.

A plurality of storage cells 50 are distributed in an array. A first electrode 11 of a first transistor T1 is connected with a read bit line RBL, a second electrode 12 of the first transistor T1 is connected with a read word line RWL, a first gate 10 of the first transistor T1 is connected with a third electrode 21 of a second transistor T2, a fourth electrode 22 of the second transistor T2 is connected with a write bit line WBL, and a second gate 20 of the second transistor T2 is connected with a write word line WWL. The second gate 20 is reused as the back gate of the first transistor T1.

The access method includes:
during a read operation phase, applying a first voltage to a write word line connected to one or more rows of storage cells to be accessed, such that the first voltage is applied to a back gate of a first transistor in the one or more rows of storage cells, wherein the first voltage is used to adjust a threshold voltage of the first transistor to a first threshold voltage, and the first threshold voltage satisfies that the first transistor is in an off state when a storage signal is 0, and the first transistor is in an on state when the storage signal is 1;
and applying a second voltage to write word lines for storage cells in other rows that are not necessary to be accessed, such that the second voltage is applied to a back gate of a first transistor in the other rows of storage cells, wherein the second voltage is used to adjust the threshold voltage of the first transistor to a second threshold voltage, the second threshold voltage satisfies that the first transistor is in an off state in the read operation phase. That is, when the storage signal is 0 or 1, the first transistor is in the off state.

The second threshold voltage is greater than the first threshold voltage.

Since the second gate 20 is reused as the back gate of the first transistor T1, the first voltage can adjust the threshold voltage of the first transistor T1, enabling to turn on the first transistor of the storage cell to be accessed when “1” is stored, and to turn off the first transistor of the storage cell to be accessed when “0” is stored; the second voltage applying to the write word line for the unaccessed storage cell enables to adjust the threshold voltage of the first transistor of the unaccessed storage cell, such that the first transistor of the unaccessed storage cell is turned off (the first transistor is turned off regardless of that “0” or “1” is stored).

In some embodiments, the access method further includes:
during the read operation phase, applying a third voltage to a read bit line connected to one or more rows of storage cells to be accessed, and applying a fourth voltage to a read word line connected to one or more rows of storage cells to be accessed, and accessing one or more rows of storage cells according to changes in electrical signals of the read bit line.

In some embodiments, there is a voltage difference between the third voltage and the fourth voltage.

And accessing the one or more rows of storage cells according to the changes in the electrical signal of the read bit line includes accessing one or more rows of storage cells according to a change in a current of the read bit line, or accessing one or more rows of storage cells according to a change in a voltage of the read bit line.

According to the above, data stored in one or more rows of storage cells can be read.

In some embodiments, the access method further includes a write operation of applying an on voltage to a write word line connected to one or more rows of storage cells to be written so that a second transistor of the one or more rows of storage cells to be written is turned on, and a storage signal is written to a first gate of a first transistor of the storage cell to be written through the write bit line.

In some embodiments, the access method further includes:
after the write operation is completed, applying an off voltage to write word lines for each storage cell in all rows so that each second transistor is turned off and the threshold voltage of the first transistor in this case is a third threshold voltage;
the third threshold voltage is greater than the first threshold voltage and less than the second threshold voltage.

For example, as shown in FIGS. 1 and 2, if the first row of storage cells in FIG. 1 is accessed, an operating principle of the memory access method is as follows.

It should be noted that the first row described below can actually be understood as a row of storage cells to be accessed, and for all the following descriptions, the row of storage cells to be accessed is taken as the first row in FIG. 1 as an example.
1. During the write operation, an on voltage (high level) is applied to the write word line WWL1 connected to the first row of storage cells to be written, so that the second transistors T2 of the storage cells to be written are turned on, and the storage signal is written to the storage nodes SN of the storage cells to be accessed through the write bit lines WBL1 to WBLn (the first gate of the first transistor is used as the storage node SN). For example, the storage signal 0 or 1 is written to the storage cell through the write bit line, and corresponding charges for storing 1 or 0 are stored in the storage node SN, i.e., the first gate of the first transistor.

After the write operation is completed, an off voltage (e.g. 0 V) is applied to the write word lines for each storage cell in all rows, so that each write transistor is turned off.
2. In the read operation, a suitable voltage, such as the first voltage (positive voltage), is applied to the write word line WWL1 connected to the first row of storage cells to be accessed. That is, the first voltage is applied to the back gates of the first transistors T1 (read transistor) of the first row of storage cells to be accessed, and the threshold voltage of the read transistor is adjusted, so that the first transistor T1 of the first row of storage cells to be accessed is in the off state when the storage signal of the storage node SN is 0 and is in the on state when the storage signal is 1, and the second voltage (negative voltage) is applied to the write word lines (WWL2, WWL3, . . . WWLm) of other rows of storage cells (storage cells in rows other than the first row) that are not necessary to be accessed, wherein the second voltage is less than the off voltage. That is, the lower voltage, i.e., the second voltage (negative voltage), is applied to the back gates of the first transistors T1 (read transistor) of the storage cells in other rows that are not necessary to be accessed. Compared to the off voltage input after the write operation is completed, raising the threshold voltage of the first transistor T1 enables that the first transistor T1 in other rows of unaccessed storage cells is turned off or closed more thoroughly. Crosstalk between the read word line RWL and the read bit line RBL of the storage cell to be accessed is reduced because the first transistors T1 of the storage cells in the other rows that are not necessary to be accessed are turned off more completely.

If a Sense Amplifier SA is a current-type amplifier, during a read sense phase, the third voltage is applied to the read bit line RBLn connected to the first row of storage cells to be accessed, and a reference voltage, such as the fourth voltage, is applied to the read word line RWL1 connected to the first row of storage cells to be accessed, wherein there is a voltage difference between the third voltage and the fourth voltage. During the read phase, it is determined that the read signal is 1 or 0 according to a change of an instantaneous current in the read bit line. When the change of the instantaneous current exceeds a preset current value, the read signal is 1. When the change of the instantaneous current does not exceed the preset current value or there is no change, the read signal is 0.

When the sense amplifier SA is a voltage-type amplifier, during the read sense phase, the third voltage is applied to the read bit line RBLn connected to the first row of storage cells to be accessed, and the reference voltage, such as the fourth voltage, is applied to the read word line RWL1 connected to the first row of storage cells to be accessed, wherein there is a voltage difference between the third voltage and the fourth voltage. When a change of an instantaneous voltage exceeds a preset voltage value, the read signal is 1, and when the change of the instantaneous voltage does not exceed the preset voltage value or there is no change, the read signal is 0.

As described above, only the first row of storage cells which is accessed is taken as an example. Alternatively, any one or more rows of storage cells may be accessed. For example, only the third row of storage cells is accessed, or the second to fourth rows of storage cells are accessed, and the access method therefor is similar to the access method described above, which will not be repeated here.

In the abovementioned embodiments of the present disclosure, at least the following beneficial effects can be achieved.
1) According to the memory provided in the embodiments of the present disclosure, the gate of the write transistor (the second transistor T2) is also used as the back gate of the read transistor (the first transistor T1), so that the read transistor is not necessarily to be a dual-gate structure, which can reduce the process difficulty and be widely used. In addition, by applying the second voltage to the gate of the write transistor of the unaccessed storage cell, i.e., applying the second voltage to the back gate of the read transistor, the threshold voltage of the read transistor is adjusted, the read transistor of the unaccessed storage cell is turned off, the data can be read reliably, and crosstalk can be avoided or effectively reduced.
2) The threshold voltage of the read transistor (left transistor) can be controlled by controlling the second gate 20 of the write transistor. In the present disclosure, by setting the dielectric constant K value of the second gate dielectric layer 24 to be greater than 7, the control force is stronger, and the threshold voltage of the read transistor can be controlled better.
3) The memory provided in the embodiments of the present disclosure is a 3D memory including a plurality of layers of storage cells 50 stacked along a direction perpendicular to the substrate 100. According to the 2T0C structure scheme provided in the embodiments of the present disclosure, the gate of the second transistor is a vertical structure and the channel is a horizontal channel and the second transistor is not stacked with the first transistor, so that the size of the storage cell in a direction perpendicular to the substrate can be reduced, and the 3D stack of the 2T0C storage cell with a compact structure can be conveniently manufactured, thus simplifying the process and reducing the cost.

Those skilled in the art can understand that acts, measures and solutions in various operations, methods, and the process already discussed in the present disclosure may be alternated, changed, combined or deleted. Further, other acts, measures and solutions in various operations, methods and processes already discussed in the present disclosure may also be alternated, changed, rearranged, divided, combined or deleted. Further, acts, measures and schemes in the prior arts having the same functions with those in various operations, methods and processes disclosed in the present disclosure may also be alternated, changed, rearranged, divided, combined or deleted.

Terms “first” and “second” are only used for description and should not be construed as indicating or implying relative importance or implicitly indicating the number of indicated technical features. Therefore, features defined by “first” and “second” may explicitly or implicitly include one or more such features. In the descriptions of the present invention, “plurality of” means two or more than two, unless otherwise specified.

It should be understood that although various acts in the flowcharts of the drawings is shown in the order as indicated by arrows, these acts are not necessarily executed sequentially in the order as indicated by the arrows. Unless explicitly stated herein, the execution of these acts is not strictly limited in order, and may be executed in other orders. Furthermore, at least a part of the acts in the flowcharts of the drawings may include a plurality of sub-acts or stages, which may not necessarily be completed at the same time, but may be executed at different time, and the execution order may not necessarily be carried out sequentially, but may be executed sequentially or alternately with other acts or at least a part of sub-acts or stages of other acts.

The above is only part of the implementations of the present disclosure, and it should be noted that for those of ordinary skills in the art, without departing from the principles of the present disclosure, various improvements and modifications may be made, and these improvements and modifications should also be regarded as being covered by the protection scope of the present disclosure.

1. A memory comprising a plurality of storage cells;
wherein the storage cells comprise a first transistor and a second transistor, wherein the first transistor is configured as a read transistor and the second transistor is configured as a write transistor, and the first transistor and the second transistor are sequentially distributed in a direction parallel to a substrate;
the first transistor comprises a first gate, a first semiconductor layer, a first electrode, a second electrode and a back gate, and the second transistor comprises a second gate, a second semiconductor layer, a third electrode and a fourth electrode;
the first gate extends in the direction parallel to the substrate, the first semiconductor layer surrounds and is insulated from the first gate; the second gate extends in a direction perpendicular to the substrate, the second semiconductor layer surrounds and is insulated from the second gate;
the first gate is connected with the second semiconductor layer, and the first gate is connected with the third electrode, such that the first transistor is connected with the second transistor;
the first semiconductor layer is connected with the second semiconductor layer, and the second gate is reused as the back gate of the first transistor.

2. The memory of claim 1, wherein
both the first transistor and the second transistor are N-type transistors.

3. The memory of claim 1, wherein the first transistor further comprises a first gate dielectric layer, and the second transistor further comprises a second gate dielectric layer;
the first gate dielectric layer is disposed between the first gate and the first semiconductor layer, and surrounds the first gate;
the second gate dielectric layer is disposed between the second gate and the second semiconductor layer, and surrounds the second gate;
a dielectric constant K value of the first gate dielectric layer is less than a dielectric constant K value of the second gate dielectric layer.

4. The memory of claim 3, wherein
the dielectric constant K value of the first gate dielectric layer is less than 7, and the dielectric constant K value of the second gate dielectric is greater than 7.

5. The memory of claim 1, wherein
on a plane perpendicular to the substrate, there is an overlapping region in which an orthographic projection of the first gate is overlapped with an orthographic projection of the second gate.

6. The memory of claim 1, wherein
both the first electrode and the second electrode are connected with the first semiconductor layer;
the fourth electrode is connected with the second semiconductor layer;
in a cross section perpendicular to the substrate, all of the first electrode, the second electrode, and the first gate are located on a first side of the second gate, and the fourth electrode is located on a second side of the second gate, the first side and the second side are opposite to each other.

7. A memory comprising a storage cell comprising: a read transistor and a write transistor;
wherein the read transistor comprises a first gate and a back gate, the first gate extends along a first direction, the first gate comprises a sidewall and two ends, the at least one end and the sidewall are wrapped by one continuous first semiconductor layer, and the first semiconductor layer is insulated from the first gate by a first gate dielectric layer;
the write transistor comprises a second gate extending along a second direction, the second gate has a sidewall surrounded by a second semiconductor layer, a first semiconductor layer of a region corresponding to an end of the first gate wrapped by the first semiconductor layer is a part of the second semiconductor layer; the second gate is reused as the back gate.

8. A semiconductor equipment comprising:
a read transistor and a write transistor, wherein the read transistor comprises a first gate and a back gate, the write transistor comprises a second gate;
the back gate of the read transistor is connected with the second gate of the write transistor.

9. The semiconductor equipment of claim 8, comprising a storage cell; wherein the storage cell comprises the read transistor and the write transistor;
the read transistor comprises the first gate and the back gate, and the write transistor comprises the second gate;
extension directions of the first gate and the second gate are perpendicular to each other;
an outer sidewall of the first gate is surrounded by a first semiconductor layer, and an outer sidewall of the second gate is surrounded by a second semiconductor layer, the first semiconductor layer is connected with the second semiconductor layer;
the first gate is connected with the second semiconductor layer;
the second gate is reused as the back gate.

10. The semiconductor equipment of claim 9, wherein
the first semiconductor layer and the second semiconductor layer are made of a same material, and the first semiconductor layer and the second semiconductor layer are of an integral structure.

11. The semiconductor equipment of claim 9, wherein
the first semiconductor layer and the second semiconductor layer are made of different materials, and the first semiconductor layer is coupled to the second semiconductor layer.

12. An access method for the memory of any one of claims 1 to 7, wherein the memory comprises a plurality of read bit lines, a plurality of read word lines, a plurality of write bit lines, and a plurality of write word lines; a plurality of storage cells are distributed in an array; the first electrode of the first transistor is connected with a read bit line, the second electrode of the first transistor is connected with a read word line, the first gate of the first transistor is connected with the third electrode of the second transistor, the fourth electrode of the second transistor is connected with a write bit line, and the second gate of the second transistor is connected with a write word line; the second gate is reused as the back gate of the first transistor;
the access method comprises:
during a read operation phase, applying a first voltage to a write word line connected to one row of storage cells to be accessed, such that the first voltage is applied to a back gate of a first transistor in the one row of storage cells, wherein the first voltage is used to adjust a threshold voltage of the first transistor to a first threshold voltage, and the first threshold voltage satisfies that the first transistor is in an off state when a storage signal is 0, and the first transistor is in an on state when the storage signal is 1;
and applying a second voltage to write word lines for storage cells in other rows that are not necessary to be accessed, such that the second voltage is applied to a back gate of a first transistor in the other rows of storage cells, wherein the second voltage is used to adjust the threshold voltage of the first transistor to a second threshold voltage, the second threshold voltage satisfies that the first transistor is in an off state in the read operation phase;
the second threshold voltage is greater than the first threshold voltage.

13. The access method for the memory of claim 12, further comprising:
a write operation of applying an on voltage to a write word line connected to one row of storage cells to be written, such that a second transistor of the one row of storage cells to be written is turned on, and writing a storage signal to a first gate of a first transistor of the one row of storage cells to be written through the write bit line.

14. The access method for the memory of claim 13, further comprising:
after the write operation is completed, applying an off voltage to write word lines for various storage cells in all rows, such that each second transistor is turned off and the threshold voltage of the first transistor in this case is a third threshold voltage;
the third threshold voltage is greater than the first threshold voltage and less than the second threshold voltage.

15. An electronic device comprising the memory of any one of claims 1 to 6, or comprising the memory of claim 7, or comprising the semiconductor equipment of any one of claims 8 to 11.
